(19) United States
(12) Patent Application Publication
(10) Pub. No.: US 2025/0132675 A1
(43) Pub. Date: Apr. 24, 2025

(54) VOLTAGE REGULATOR CIRCUIT, CORRESPONDING DRIVER CIRCUIT, DEVICE AND METHOD OF OPERATION

(71) Applicant: STMicroelectronics International N.V., Geneva (CH)

(72) Inventors: Marco Giovanni FONTANA, Milano (IT); Romino CRETONE, Milano (IT)

(73) Assignee: STMicroelectronics International N.V., Geneva (CH)

(21) Appl. No.: 18/906,913

(22) Filed: Oct. 4, 2024

(30) Foreign Application Priority Data
Oct. 20, 2023 (IT) 102023000021924

(51) Int. Cl. H02M 3/158; H02M 1/088; H03K 17/687

(52) U.S. Cl. CPC H02M 3/158; H02M 1/088; H03K 17/6871; H03K 2217/0063; H03K 2217/0072

(57) ABSTRACT

Provided is voltage regulator circuit including an input node for receiving an input supply voltage, an output node for producing an output regulated voltage, and a switchable pass element arranged between the input and output nodes. A comparator circuit compares the output regulated voltage to a dynamic threshold to produce a control signal to control the switchable pass element. The control signal being asserted results in the switchable pass element being turned on, and vice-versa. A threshold selection and shaping circuit shapes the output regulated voltage or the dynamic threshold so that: (i) in response to assertion of the control signal, the difference between the dynamic threshold and the output regulated voltage is abruptly increased and subsequently gradually decreased towards a target static value, and (ii) in response to de-assertion of the control signal, the difference is abruptly increased and subsequently gradually decreased towards a target static value.

### BACKGROUND

### Technical Field

The description relates to switching (i.e., on/off) voltage regulators and their control circuits.

For instance, switching voltage regulators may be implemented in driver circuits for half-bridge switching circuits with high-side bootstrap architecture. High-voltage (HV) half-bridge switching circuits may be used in various applications such as motor driver (motor control) devices, electronic ballasts for fluorescent lamps, power supply devices, power converters and the like.

### Technological Background

Gallium nitride (GaN) power transistors are being increasingly used in half-bridge switching circuits in the place of conventional power transistors (such as conventional silicon MOS field-effect transistors or insulated-gate bipolar transistors, IGBT) with the aim of improving the overall efficiency of the switching circuit. For instance, GaN power transistors may provide lower gate capacitance and higher switching speed.

Driver circuits for such GaN half-bridge circuits are known, for instance, from document U.S. Pat. No. 11,476,845 B2, which is hereby incorporated herein by reference in its entirety. In brief, this document discloses a half-bridge driver that includes a high-side bootstrap path, as exemplified in FIG. 1 annexed herein. The half-bridge driver HBD has a pair of input terminals (e.g., a positive supply terminal 100a and a reference supply terminal 100b or ground) configured to receive therebetween a power supply voltage from an external power source PS. In this application, the power supply voltage is a sensor supply voltage V_{CC}, but more generally the power supply voltage may be referred to as V_{supply}. The half-bridge driver HBD is further configured to receive low-voltage control signals IN_{HS}, IN_{LS} for controlling the high-side and low-side switches HS, LS of the half-bridge. The half-bridge driver HBD includes a high-side gate driver circuit 12a and a low-side gate driver circuit 12b. The low-side gate driver circuit 12b receives the low-side low-voltage control signal IN_{LS}, and produces between a pair of output terminals 120b, 102b a respective low-side gate control signal LVG for the low-side switch LS of the half-bridge circuit. The output terminal 102b is coupled (internally to the driver HBD) to the ground terminal 100b. Alternatively, the integrated circuit HBD may have a single ground pin. The high-side gate driver circuit 12a receives the high-side low-voltage control signal IN_{HS} via a level shifter circuit 14, and produces between a pair of output terminals 120a, 102a a respective high-side (shifted) gate control signal HVG for the high-side switch HS of the half-bridge circuit. The output terminal 102a is the switching node of the half-bridge circuit, where the output voltage V_{OUT} is produced. The low-side gate driver circuit 12b is biased by the sensor supply voltage V_{CC}, and the high-side gate driver circuit 12a is biased by a bootstrap voltage V_{BO} in a floating section FS of the half-bridge driver circuit. In particular, the bias voltage V_{BO} of the high-side gate driver circuit 12a is provided between the switching node 102a of the half-bridge circuit (acting as a floating ground) and a floating supply node 104 (i.e., a floating positive supply voltage higher than the floating ground). The floating supply node 104 is connected to the switching node 102a of the half-bridge circuit via a bootstrap capacitor C_{B} (e.g., external to the integrated circuit of the half-bridge driver circuit HBD). Further, the floating supply node 104 is coupled (internally to the integrated circuit of the half-bridge driver circuit HBD) to the positive terminal 100a via a bootstrap path that includes two transistors Q3 and Q1′. In particular, a first transistor Q3 (e.g., n-channel MOS transistor) operating as an active diode has its conductive channel connected between the positive terminal 100a and an intermediate supply node 106 (or “decoupling node”), and a second transistor Q1′ (e.g., p-channel MOS transistor) operating as a current limiter has its conductive channel connected between the decoupling node 106 and the floating supply node 104. Transistors Q3 and Q1′ are arranged so as to have “back-to-back” body diodes (D3 and D1′, respectively) in the bootstrap path from node 100a to node 104. The active diode Q3 and the current limiter Q1′ are controlled by respective control circuits 60 and 62, with the control circuit 60 of the active diode Q3 being implemented in the low-voltage section of the half-bridge driver HBD and the control circuit 62 of the current limiter Q1′ being implemented in the floating section FS of the half-bridge driver HBD. The high-side gate driver circuit 12a is supplied between nodes 104 and 102a (voltage V_{BO}), while the level shifter circuit 14 has a first portion supplied by the external supply source PS (sensor supply voltage V_{CC}) and a second potion supplied by the decoupling node 106 (intermediate supply voltage V_{S}).

In the architecture of FIG. 1, the switching operation of the half-bridge circuit results in a bootstrap recharge phase (during which the high-side switch HS is off and the low-side switch LS is on) and a bootstrap supply phase (during which the high-side switch HS is on and the low-side switch LS is off). In the bootstrap recharge phase, the switching node 102a of the half-bridge is coupled to ground and the bootstrap capacitor C_{B} is charged by a (controlled) current flowing from the positive supply terminal 100a to the floating supply node 104 through the active diode Q3 and the current limiter Q1′. In particular, during the bootstrap recharge phase, the active diode Q3 implements on/off regulation of voltage V_{S} to reduce (e.g., minimize) the voltage drop between terminal 100a and node 106 (i.e., to maintain voltage V_{S} close to voltage V_{CC}), and the current limiter Q1′ implements on/off regulation of voltage V_{BO} to maintain voltage V_{BO} in the desired voltage range (e.g., setting it to 5.4 V), thus operating as a non-dissipative clamp. In the bootstrap supply phase, the switching node 102a of the half-bridge is coupled to a positive bus pin 108 providing a positive bus voltage V_{B}US, and the charge stored in the bootstrap capacitor C_{B} supplies the high-side gate driver circuit 12a. At a subsequent switching cycle, during another bootstrap recharge phase, the charge in the bootstrap capacitor is restored.

In the known solution discussed above, the decoupling node 106 is capacitively coupled to the control (e.g., gate) terminal of transistor Q3 (e.g., by a gate-drain parasitic capacitance C_{gd_Q3}), to the control (e.g., gate) terminal of transistor Q1′ (e.g., by a gate-source parasitic capacitance C_{gd_Q1″}), and to ground (e.g., via other parasitic capacitances C_{Vs0}). During the bootstrap recharge phase, the bootstrap path operates to maintain a voltage regulation at the decoupling node 106 and at the floating supply node 104. While the bootstrap voltage V_{BO} across the bootstrap capacitor C_{B} (i.e., between the floating supply node 104 and the switching node 102a, V_{BO}=V_{BOOT}−V_{OUT}) is raised to a desired voltage (e.g., 5.4 V), the voltage at the decoupling node 106 is regulated to a value close to the sensor supply voltage V_{CC}. During the bootstrap recharge phase, regulation of the bootstrap voltage is not substantially affected by clock feedthrough (or gate feedthrough—i.e., the result of the coupling between a control signal on an analog switch and the analog signal passing through the switch), insofar as the bootstrap capacitor C_{B} has typically a great capacitance compared to the parasitic capacitances at the decoupling node 106. However, in each regulation the parasitic capacitances C_{gd_Q3} and C_{gd_Q1} are not negligible and are comparable to the parasitic capacitance C_{Vs0}. For instance, the capacitive ratio C_{gd_Q3}/(C_{Vs0}+c_{gd_Q3}) may be about 0.5. Therefore, the regulation of the voltage V_{S} at the intermediate supply node 106 may be prone to clock feedthrough.

The application discussed above represents an example of a switching regulator (i.e., providing regulation of voltage V_{S} at node 106 via switch Q3) that is possibly affected by clock feedthrough. Other applications may be affected by a similar issue. Therefore, there is a need in the art to provide improved control circuits for switching voltage regulators that facilitate countering the clock feedthrough phenomenon. Such control circuits can be applied, for example, to the control of an active diode switch in a half-bridge driver.

### BRIEF SUMMARY

An object of one or more embodiments is to contribute in providing such improved switching voltage regulators, which may be used to implement the active diode switch of a gate driver circuit.

According to one or more embodiments, such an object can be achieved by a voltage regulator circuit having the features set forth in the claims that follow.

One or more embodiments may relate to a corresponding half-bridge driver circuit.

One or more embodiments may relate to a corresponding electronic device (e.g., an active clamp flyback converter, or a resonant LLC converter).

One or more embodiments may relate to a corresponding method of operation.

The claims are an integral part of the technical teaching provided herein in respect of the embodiments.

According to an aspect of the present description, a voltage regulator circuit includes an input node configured to receive an input supply voltage, an output node configured to produce an output regulated voltage, a switchable pass element having a selectively conductive channel arranged between the input node and the output node, and a comparator circuit configured to compare the output regulated voltage to a dynamic threshold to produce a control signal to control switching of the switchable pass element. The control signal being asserted results in the switchable pass element being turned on, and the control signal being de-asserted results in the switchable pass element being turned off. The voltage regulator circuit further includes a threshold selection and shaping circuit configured to shape the output regulated voltage and/or the dynamic threshold so that:
in response to assertion of the control signal, the difference between the dynamic threshold and the output regulated voltage is abruptly increased and subsequently gradually decreased towards a target static value; and
in response to de-assertion of the control signal, the difference between the output regulated voltage and the dynamic threshold is abruptly increased and subsequently gradually decreased towards a target static value.

One or more embodiments may thus provide a switching voltage regulator that applies a “dynamic hysteresis” approach to the control of the pass element, so that the hysteresis width is enlarged on demand to include the noise peaks of the regulated signal, and the “excessive” negative feedback that could lead to an uncontrolled on/off oscillating regime is inhibited.

According to another aspect of the present description, a half-bridge driver circuit includes a positive supply pin and a ground pin configured to receive therebetween a power supply voltage, a first control pin configured to receive a low-voltage high-side control signal for controlling a high-side switch of a half-bridge circuit, and a second control pin configured to receive a low-voltage low-side control signal for controlling a low-side switch of the half-bridge circuit. The half-bridge driver circuit further includes a high-side gate driver circuit configured to receive the low-voltage high-side control signal via a level shifter circuit and produce a respective high-side gate control signal (HVG), and a low-side gate driver circuit configured to receive the low-voltage low-side control signal and produce a respective low-side gate control signal. The high-side gate driver circuit is biased between a floating supply pin and a switching pin of the half-bridge driver circuit, and the floating supply pin is coupled to the positive supply pin via a bootstrap path. The bootstrap path includes a voltage regulator circuit according to an aspect of the present description, which has its input node connected to the positive supply pin and its output node connected to a decoupling node internal to the half-bridge driver circuit, and a current limiter circuit arranged between the decoupling node and the floating supply pin.

According to another aspect of the present description, an electronic device includes a half-bridge driver circuit according to an aspect of the present description, a high-side switch coupled between a positive bus pin and the switching pin of the half-bridge driver circuit, a low-side switch coupled between the switching pin of the half-bridge driver circuit and the ground pin, and a bootstrap capacitor coupled between the floating supply pin and the switching pin of the half-bridge driver circuit.

According to another aspect of the present description, a method of operating a voltage regulator circuit according to an aspect of the present description includes:
receiving an input supply voltage at the input node;
producing an output regulated voltage at the output node;
comparing the output regulated voltage to a dynamic threshold at the comparator circuit to produce a control signal to control switching of the switchable pass element, turning on the switchable pass element in response to the control signal being asserted, and turning off the switchable pass element in response to the control signal being de-asserted; and
shaping the output regulated voltage and/or the dynamic threshold at the threshold selection and shaping circuit, abruptly increasing and subsequently gradually decreasing towards a target static value the difference between the dynamic threshold and the output regulated voltage in response to assertion of the control signal, and abruptly increasing and subsequently gradually decreasing towards a target static value the difference between the output regulated voltage and the dynamic threshold in response to de-assertion of the control signal.

### BRIEF DESCRIPTION OF THE SEVERAL VIEWS OF THE DRAWINGS

One or more embodiments will now be described, by way of example, with reference to the annexed figures, wherein:

FIG. 1, previously presented, is a circuit block diagram exemplary of a half-bridge switching circuit and related half-bridge driver including a high-side bootstrap architecture;

FIG. 2 is a circuit block diagram exemplary of a bootstrap path of a half-bridge driver, showing a possible implementation of a control circuit for the active diode of the bootstrap path;

FIG. 3 is a diagram including possible waveforms of signals in the circuit of FIG. 2, showing an unwanted oscillation regime due to clock feedthrough;

FIG. 4 is a diagram including possible waveforms of signals in the circuit of FIG. 2, where the voltage regulation is subject to freezing to counter clock feedthrough;

FIG. 5 is a diagram including possible waveforms of signals in the circuit of FIG. 2, where the hysteresis width is enlarged to counter clock feedthrough;

FIG. 6 is a diagram including possible waveforms of signals in the circuit of FIG. 2, showing an unwanted oscillation regime due to clock feedthrough;

FIG. 7 is a diagram including possible waveforms of signals in one or more embodiments of the present description, showing the use of dynamic hysteresis for regulating the output to suppress the oscillation regime due to clock feedthrough;

FIG. 8 is a schematic (e.g., conceptual) circuit diagram exemplary of a control circuit configured to control the switching element of a switching regulator with dynamic hysteresis, according to one or more embodiments of the present description, operating according to the waveforms of FIG. 7;

FIG. 9 is a circuit diagram exemplary of a control circuit configured to control the switching element of a switching regulator with dynamic hysteresis, according to one or more embodiments of the present description, based on the concept of FIGS. 7 and 8;

FIG. 10 is a diagram including possible waveforms of signals in the circuit of FIG. 9, showing the use of dynamic hysteresis;

FIG. 11 is a circuit diagram exemplary of a control circuit configured to control the active diode driver of a bootstrap path with dynamic hysteresis, according to one or more embodiments of the present description;

FIG. 12 is a circuit diagram exemplary of small-signal operation of the circuit of FIG. 11;

FIGS. 13 and 14 are diagrams showing possible time-modulation of the resistance of certain resistors in the circuit of FIG. 12;

FIG. 15 is a diagram including possible waveforms of signals in the circuit of FIG. 2, where the unwanted oscillation regime is suppressed by implementing a dynamic hysteresis control according to one or more embodiments of the present description; and

FIG. 16 is a circuit block diagram exemplary of a switching voltage regulator with hysteresis to which dynamic hysteresis control according to one or more embodiments of the present description is applicable.

### DETAILED DESCRIPTION

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is included in at least one embodiment. Hence, phrases such as “in an embodiment” or “in one embodiment” that may be present in one or more points of the present description do not necessarily refer to one and the same embodiment. Moreover, particular configurations, structures, or characteristics may be combined in any adequate way in one or more embodiments.

The headings/references used herein are provided merely for convenience and hence do not define the extent of protection or the scope of the embodiments.

Throughout the figures annexed herein, unless the context indicates otherwise, like parts or elements are indicated with like references/numerals and a corresponding description will not be repeated for the sake of brevity.

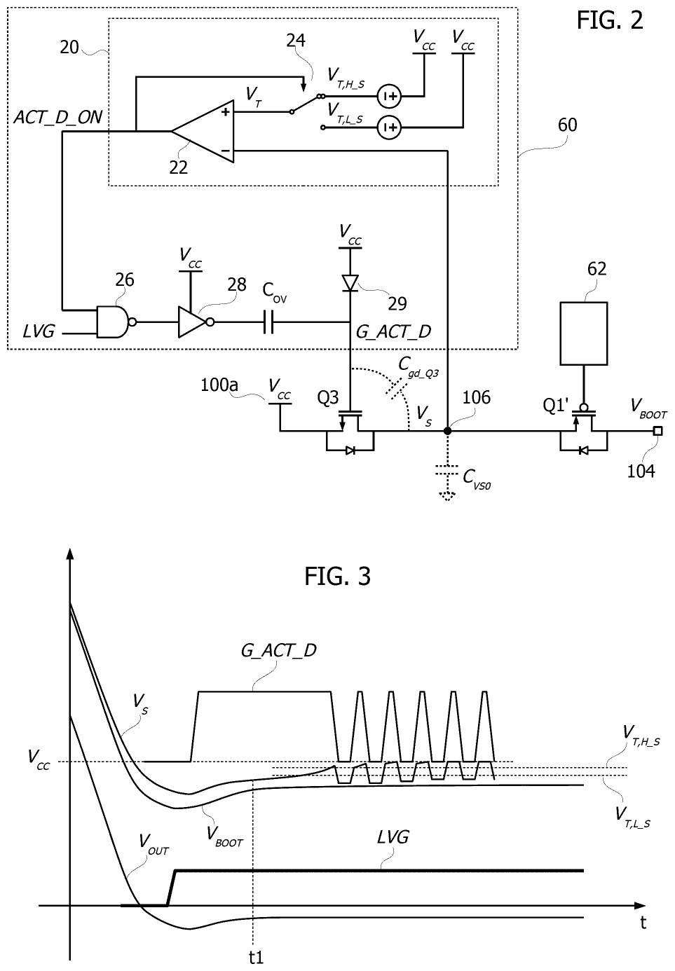

By way of introduction to the detailed description of exemplary embodiments, reference may be made to FIGS. 2 to 5, discussed in the following.

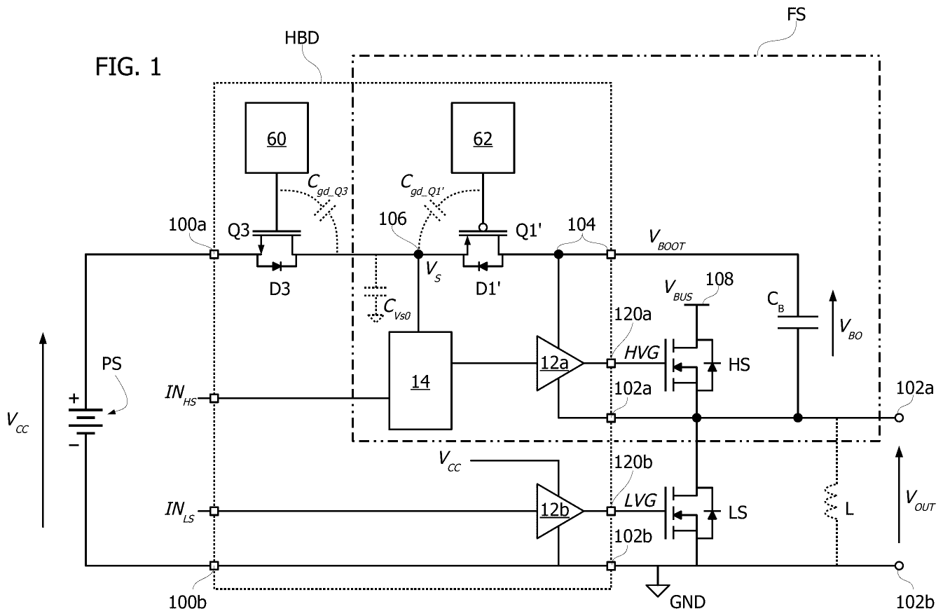

FIG. 2 is a circuit block diagram exemplary of a bootstrap path in a half-bridge driver as discussed with reference to FIG. 1, additionally showing a possible implementation of the control circuit 60 for the active diode Q3 (circuit 60 being also referred to as “active diode driver” in the present application). The active diode driver 60 of FIG. 2 implements a comparator with static hysteresis for the regulation of the intermediate supply voltage V_{S}. In particular, the driver 60 includes a voltage sensor 20 that includes a comparator 22 with a switchable voltage reference V_{T}. The comparator 22 has a first (e.g., negative) input terminal coupled to node 106 to sense voltage V_{S}, and a second (e.g., positive) input terminal alternatively couplable to a first (e.g., higher) static threshold voltage V_{T,H_S} or to a second (e.g., lower) static threshold voltage V_{T,L_S} via a switch 24. In this application, both threshold voltages V_{T,H_S} and V_{T,L_S} are referenced to the sensor supply voltage V_{CC}, but more generally the threshold voltages may be referenced to a reference voltage V_{ref}. Therefore, comparison of the intermediate supply voltage V_{S} for regulation purposes is implemented with a static hysteresis by alternatively selecting the reference voltage V_{T} (V_{T,H_S} or V_{T,L_S}) for the comparator 22, which produces an activation signal ACT_D_ON for the active diode Q3. Choice (e.g., sizing) of the threshold voltages V_{T,H_S} and V_{T,L_S} and their gap is a matter of trade-off between the requirement of noise filtering (which prefers a larger gap between V_{T,H_S} and V_{T,L_S}) and the regulation accuracy (which prefers a smaller gap between V_{T,H_S} and V_{T,L_S}). The active diode driver 60 further includes a NAND gate 26 configured to apply NAND logic processing to signal ACT_D_ON and to the low-side gate control signal LVG. The output signal produced by NAND gate 26 is passed to an inverter 28 that has its output terminal coupled to the first terminal of a pumping capacitor C_{OV}. The second terminal of the pumping capacitor C_{OV} is coupled to the control (e.g., gate) terminal of the active diode transistor Q3. Further, a diode 29 has an anode terminal configured to receive the sensor supply voltage V_{CC} and a cathode terminal coupled to the control (e.g., gate) terminal of the active diode transistor Q3. Thus, a control signal G_ACT_D for the active diode transistor Q3 is produced at the control (e.g., gate) terminal of transistor Q3.

FIG. 3 is a diagram including possible waveforms of signals in the circuit of FIG. 2, in particular: the sensor supply voltage V_{CC} (dotted line), the static threshold voltages V_{T,H_S} and V_{T,L_S} (dotted lines), the intermediate supply voltage V_{S} at node 106 (solid line), the floating supply voltage V_{BOOT} at node 104 (solid line), the output voltage V_{OUT} at the switching node 102a (solid line), the low-side gate control signal LVG (solid line), and the active diode control signal G_ACT_D (solid line). The waveforms of FIG. 3 show that use of a voltage sensor 20 with static hysteresis to regulate the voltage V_{S} at node 106 may lead, in certain cases, to an uncontrolled on/off oscillating regime. In fact, each on/off commutation of the active diode Q3 may produce on the intermediate supply voltage V_{S}, due to the capacitive coupling C_{gd_Q3}, an overshoot/undershoot that can exceed the hysteresis window (i.e., increase voltage V_{S} above V_{T,H_S} or decrease voltage V_{S} below V_{T,L_S}), thereby triggering an uncontrolled on/off oscillating regime of transistor Q3. The oscillation frequency may depend on the regulation response delay, and can be relatively high (e.g., about 50 MHz). In particular, when the desired bootstrap voltage V_{BO} (e.g., 5.4 V) is reached (see, e.g., instant t1 in FIG. 3), the current limiter Q1′ is switched off and node 106 is disconnected from the bootstrap capacitor C_{B}. The coupling coefficient between node 106 and the gate terminal of transistor Q3 is big enough to trigger a clock feedthrough and eventually cause the undesired on/off oscillating regime. The on/off oscillating regime can last for a large portion of the operating cycle of the device, resulting in a high current consumption from the external power source (e.g., about 10 mA) and/or a high noise at high frequency on the power supply. The oscillating regime can be stopped by the occurrence of at least one of the following events: (i) the current limiter Q1′ switches on, connecting node 106 to node 104 at voltage V_{BOOT}, thus filtering the coupling noise by the bootstrap capacitor C_{B}; or (ii) signal LVG (at node 120b) switches to a de-asserted state (e.g., logic low), thus forcing off the active diode Q3 (whose activation signal ACT_D_ON is gated by signal LVG at gate 26).

Certain approaches may be used to counter the clock feedthrough phenomenon. For instance, in a first approach, the gate coupling noise is compensated by an opposite noise, using a so-called charge extractor circuit. The charge extractor creates a suitable coupling with a signal that switches in a complementary way with respect to the gate signal (in this case, complementary to signal G_ACT_D). However, such a solution may be critical due to the sensitive nature of node 106, and may imply a large area occupation.

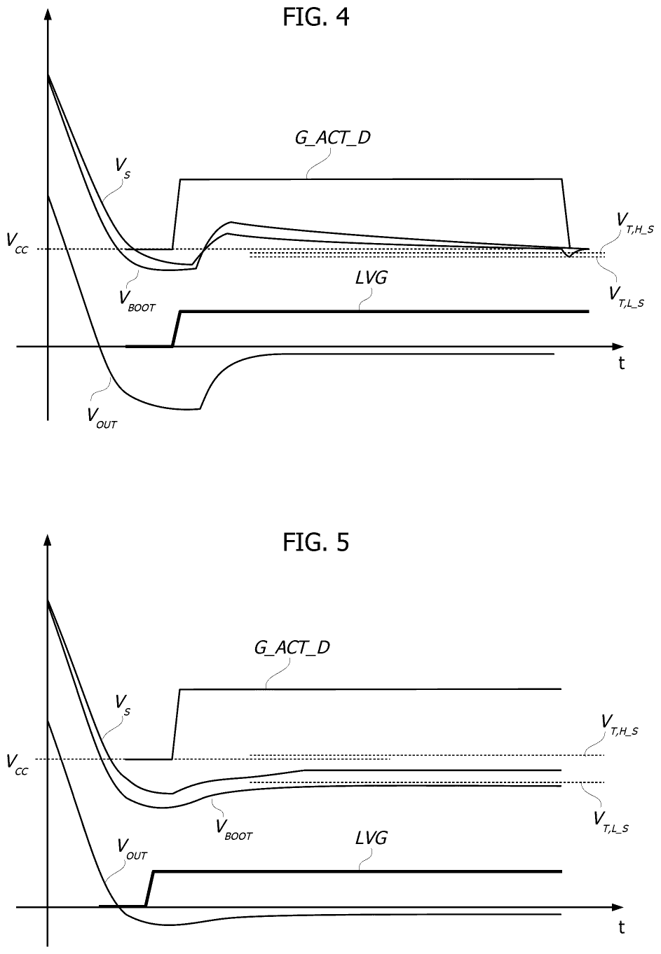

A second approach to the clock feedthrough issue is that of freezing the regulation state for a certain time interval after the gate control signal (in this example, signal G_ACT_D) has switched from one value to the other (i.e., preventing signal G_ACT_D from switching too fast), as exemplified in the diagram of FIG. 4 that shows waveforms of signals V_{CC}, V_{T,H_S}, V_{T,L_S}, V_{S}, V_{BOOT}, V_{OUT}, LVG, and G_ACT_D in such a case. The freezing phase introduced in the regulation, after a first commutation of signal G_ACT_D, holds the value of signal G_ACT_D for an appropriate time, preventing the onset of the on/off oscillating regime. However, such an approach may trigger a “back wash” current from the bootstrap capacitor C_{B} towards the positive supply terminal 100a (the following conditions are assumed: the bootstrap voltage V_{BO} is lower than the target value, e.g., 5.4 V in the whole phase, and the current limiter Q1′ is thus switched on; the recirculation is “deep” and abruptly reduced after the low-side switch LS has been turned on). Thus, this second approach may result in a degraded efficiency of the bootstrap charging phase, preventing in some cases the bootstrap voltage V_{BO} from reaching the desired voltage level.

A third approach to the clock feedthrough issue is that of choosing a larger hysteresis width for comparator 22 (i.e., a wider gap between V_{T,H_S} and V_{T,L_S}) such as to include any possible noise peak within the hysteresis window, as exemplified in the diagram of FIG. 5 which shows possible waveforms of signals V_{CC}, V_{T,H_S}, V_{T,L_S}, V_{S}, V_{BOOT}, V_{OUT}, LVG, and G_ACT_D in such a case. Here, an increase of the hysteresis width (V_{T,H_S}−V_{T,L_S}), large enough to include the peaks of voltage V_{S} arising from the coupling noise, facilitates avoiding the onset of the undesired on/off oscillating regime. In some working conditions, however, this approach may have drawbacks. Firstly, the accuracy of the regulation may be worsened insofar as the peak-to-peak amplitude of the coupling noise can be in the range of 1 V or more; the use of the active diode itself is in doubt with respect to a conventional passive diode. Secondly, if the high voltage threshold V_{T,H_S} is higher than the sensor supply voltage V_{CC}, a back wash current as previously described may be triggered and can last for a long time.

However, it has been noted that the onset of an on/off oscillating regime can be acceptable if its impact in terms of noise and current consumption is acceptable (limited), i.e., if the oscillation frequency is controlled. Even more so, if the switch is controlled by an overvoltage driver as in the example discussed with reference to FIGS. 1 and 2, some rate of on/off oscillation may even be useful, helping to recharge the gate terminal when it is in the “bootstrapped” state. Also, a small and controlled amount of back wash current can be acceptable, if its impact on the charging efficiency is acceptable too. Therefore, one or more embodiments relate to a circuit that implements a functionality to control the above-mentioned drawbacks. Such functionality is referred to as “dynamic hysteresis” and relies on time-shaping (i.e., changing over time) the hysteresis thresholds. In particular, the thresholds are shaped so as to temporarily widen the hysteresis width and gradually re-enter the “normal” (or “static”) hysteresis width, in view of the following considerations:
the “enlargement(s)” of the hysteresis width are demanded by a commutation of the regulation state (e.g., a commutation of the logic value ACT_D_ON output by the voltage sensor 20);
the enlargement(s) of the hysteresis width are set alternatively by increasing the upper threshold or by decreasing the lower threshold, such as to filter (or “tolerate”) the noise peak coming from the commutation itself; and
the re-entering phase tracks the damping phase of the noise.

It is noted that one or more embodiments may be applied to any type of switching voltage regulator, where a switching element (e.g., pass element) controls the current flow between an input voltage node and an output regulated node, based on a comparison of the output voltage to a threshold. Therefore, while the instant description will mainly refer to regulation of the intermediate supply voltage V_{S} at node 106 of the bootstrap path of a half-bridge driver circuit, it will be understood that one or more embodiments may relate to any kind of switching voltage regulator.

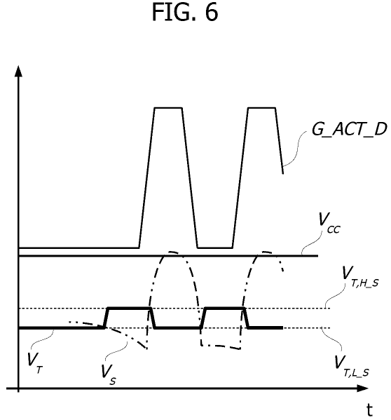

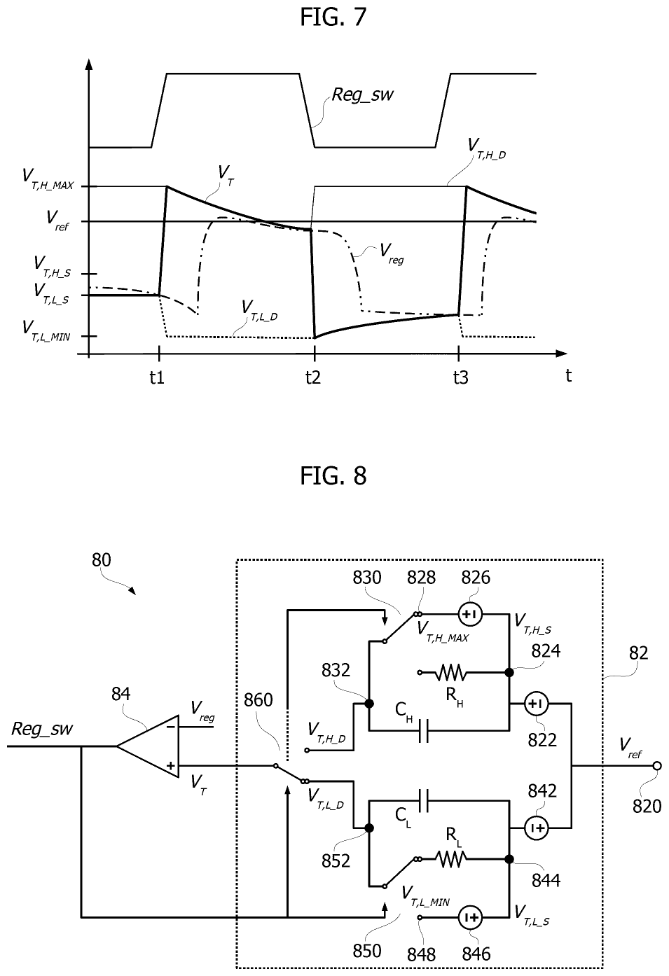

The dynamic hysteresis concept may be better understood by comparing the waveforms shown in FIGS. 6 and 7, which illustrate the behavior of signals V_{S} (or, more generally, a voltage V_{reg} regulated by the regulator), V_{T} (the selected threshold propagated to the comparator—thick line), V_{T,H_S} and V_{T,L_S} (the static thresholds), V_{CC} (or, more generally, a sensor reference voltage V_{ref}), and G_ACT_D (or, more generally, a control signal Reg_sw of the pass element of the voltage regulator). As exemplified in FIG. 6, and as previously discussed, when using conventional fixed hysteresis, on/off regulation with narrow hysteresis may trigger an uncontrolled oscillation regime, whose period is given by the sum of the delays that take place between the detection of crossing of one of the thresholds by signal V_{S} and the commutation of transistor Q3 (e.g., in FIG. 6, voltage V_{S} falling below V_{T,L_S} determines a subsequent assertion—from low to high—of signal G_ACT_D, and voltage V_{S} rising above V_{T,H_S} determines a subsequent de-assertion—from high to low—of signal G_ACT_D). As exemplified in FIG. 7, on/off regulation may be carried out adopting a dynamic hysteresis, where dynamic threshold voltages V_{T,H_D} and V_{T,L_D} are separated by a “base” gap whose amplitude may be the same as the amplitude of the static hysteresis (V_{T,H_S}−V_{T,L_S} as in FIG. 6), but can be modulated over time (as further disclosed in the following) to control the oscillating regime, thus reducing noise and power consumption.

In detail, FIG. 8 is a schematic circuit diagram exemplary of a control circuit 80 configured to produce a control signal Reg_sw for the switching element (e.g., pass element) of a switching voltage regulator, implementing dynamic hysteresis. The control circuit 80 receives a reference voltage V_{ref} (which, in the application examples of FIGS. 1 and 2, is the sensor supply voltage V_{CC}), and the regulated voltage V_{reg} produced by the voltage regulator (which, in the application examples of FIGS. 1 and 2, is the intermediate supply voltage V_{S}). As further discussed in the following, a dynamic threshold voltage V_{T} is produced by a threshold selection/shaping circuit 82 starting from the reference voltage Vᵣₑf. The dynamic threshold V_{T} and the regulated voltage V_{reg} are fed to a comparator circuit 84 that produces the control signal Reg_sw. For instance, the dynamic threshold V_{T} is fed to a positive terminal of comparator 84 and the regulated voltage V_{reg} is fed to a negative terminal of comparator 84, so that the control signal Reg_sw is asserted (e.g., high) if V_{reg}<V_{T} and is de-asserted (e.g., low) if V_{reg}>V_{T}.

In particular, in the selection/shaping circuit 82, an input node 820 receives the reference voltage V_{ref}. With regard to the shaping of the high dynamic threshold V_{T,H_D}, a voltage generator 822 coupled to node 820 adds up a fixed voltage to the reference voltage V_{ref} to produce, at a node 824, the high static threshold V_{T,H_S}. A voltage generator 826 coupled to node 824 adds up another fixed voltage to the high static threshold V_{T,H_S} to produce, at a node 828, a high maximum threshold V_{T,H_MAX}. Node 828 is selectively couplable, via a switch 830, to a node 832 where the high dynamic threshold V_{T,H_D} is produced. A discharge path (e.g., an RC circuit) is coupled between nodes 824 and 832 and is selectively activatable, via switch 830, to discharge the high dynamic voltage V_{T,H_D} at node 832 towards the high static voltage V_{T,H_S} at node 824. The switch 830 can thus either couple node 832 to node 828 to bring voltage V_{T,H_D} to the maximum value V_{T,H_MAX}, or alternatively decouple node 832 from node 828 and activate the discharge path to let voltage V_{T,H_D} decay towards the static value V_{T,H_S}. In particular, the discharge path may include a capacitor C_{H} coupled between nodes 824 and 832, and a resistor R_{H} selectively couplable between nodes 824 and 832 by switch 830. With regard to the shaping of the low dynamic threshold V_{T,L_D}, a voltage generator 842 coupled to node 820 subtracts a fixed voltage from the reference voltage V_{ref} to produce, at a node 844, the low static threshold V_{T,L_S}. A voltage generator 846 coupled to node 844 subtracts another fixed voltage from the low static threshold V_{T,L_S} to produce, at a node 848, a low minimum threshold V_{T,L_MIN}. Node 848 is selectively couplable, via a switch 850, to a node 852 where the low dynamic threshold V_{T,L_D} is produced. A charge path (e.g., an RC circuit) is coupled between nodes 844 and 852 and is selectively activatable, via switch 850, to charge the low dynamic voltage V_{T,L_D} at node 852 towards the low static voltage V_{T,L_S} at node 844. The switch 850 can thus either couple node 852 to node 848 to bring voltage V_{T,L_D} to the minimum value V_{T,L_MIN}, or alternatively decouple node 852 from node 848 and activate the charge path to let voltage V_{T,L_D} increase towards the static value V_{T,L_S}. In particular, the charge path may include a capacitor C_{L} coupled between nodes 844 and 852, and a resistor R_{L} selectively couplable between nodes 844 and 852 by switch 850. The selection/shaping circuit 82 further includes a switch 860 that alternatively couples the positive terminal of comparator 84 either to node 832 to use the high dynamic threshold V_{T,H_D} as threshold signal V_{T}, or to node 852 to use the low dynamic threshold V_{T,L_D} as threshold signal V_{T}.

Therefore, in the circuit of FIG. 8, the threshold V_{T} is selected depending on the output of comparator 84 to implement hysteresis, and before selection the selected threshold (V_{T,H_D} or V_{T,L_D}) has been pre-charged at a maximum or minimum value (V_{T,H_MAX} or V_{T,L_MIN}) by adding a further contribution (826 or 846) to the static value (V_{T,H_S} or V_{T,L_S}). The additional contribution is dynamic (or “transient”) and decays (e.g., exponentially) according to an appropriate decay time (in this example, set by an RC circuit), thus letting the dynamic thresholds reach asymptotically the corresponding static value.

Making again reference to FIG. 7, the switches 830, 850 and 860 may be controlled according to the following timing scheme, supposing that the comparator 84 is initially configured to receive the low threshold V_{T,L_D} (i.e., switch 860 is initially set to propagate voltage V_{T,L_D}, that is V_{T}=V_{T,L_D}=V_{T,L_S}). When the regulated voltage V_{reg} falls below V_{T} (time t1), the control signal Reg_sw toggles to an asserted state, and switch 860 is set to couple the comparator 84 to node 832 to receive voltage V_{T,H_D} (i.e., V_{T}=V_{T,H_D}) that was previously pre-charged to the maximum value V_{TH_MAX}. Thus, voltage V_{T} reaches the maximum value V_{T,H_MAX}. At the same time, switch 830 is set to couple node 832 to resistor R_{H} so that voltage V_{T,H_D} starts decaying towards voltage V_{T,H_S}. At the same time, on the other side, switch 850 is set to couple node 852 to node 848 so that voltage V_{T,L_D} is brought to the minimum value V_{T,L_MIN}. This configuration (i.e., V_{T}=V_{T,H_D}, V_{T,H_D} decaying towards V_{T,H_S}, and V_{T,L_D}=V_{T,L_MIN}) is maintained until the regulated voltage V_{reg} crosses V_{T} (i.e., it exceeds V_{T,H_D}, time t2). At this point, the control signal Reg_sw toggles to a de-asserted state, and switch 860 is set to couple the comparator 84 to node 852 to receive voltage V_{T,L_D} (i.e., V_{T}=V_{T,L_D}) that meanwhile has been pre-charged to the minimum value V_{T,L_MIN}. Thus, voltage V_{T} reaches the minimum value V_{T,L_MIN}. At the same time, switch 850 is set to couple node 852 to resistor R_{L} so that voltage V_{T,L_D} starts decaying towards voltage V_{T,L_S}. At the same time, on the other side, switch 830 is set to couple node 832 to node 828 so that voltage V_{T,H_D} is brought to the maximum value V_{TH_MAX}. This configuration (i.e., V_{T}=V_{T,L_D}, V_{T,L_D} decaying towards V_{T,L_S}, and V_{T,H_D}=V_{T,H_MAX}) is maintained until the regulated voltage V_{reg} crosses V_{T} again (i.e., it falls below V_{T,L_D}, time t3). At this point, a new cycle starts as from time t1.

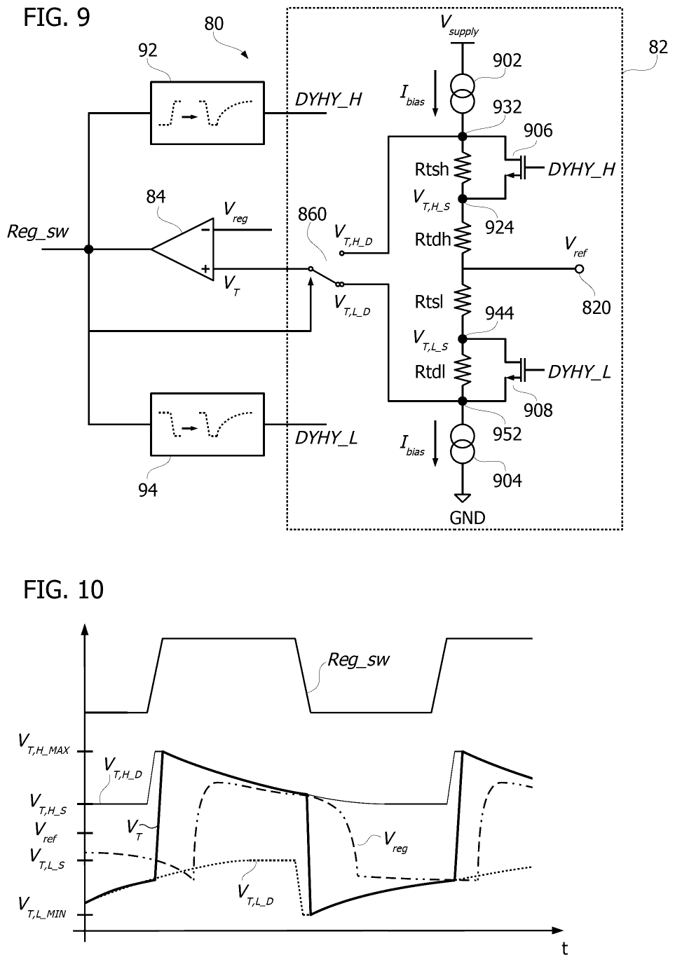

FIG. 9 is a circuit diagram exemplary of a possible circuit implementation operating according to the principle of the control circuit 80 and the threshold selection/shaping circuit 82. In this implementation, circuit 82 includes a current flow line arranged between a supply voltage V_{supply} and ground GND. The current flow line includes the following components arranged in series: a current generator 902 coupled between the supply voltage V_{supply} and a node 932 to source a bias current I_{bias}, a resistor Rtsh arranged between nodes 932 and 924, a resistor Rtdh arranged between nodes 924 and 820, a resistor Rtsl arranged between nodes 820 and 944, a resistor Rtdl arranged between nodes 944 and 952, and a current generator 904 coupled between node 952 and ground to sink the bias current I_{bias}. Additionally, a bypass transistor 906 (e.g., an n-channel MOS transistor) having a tunable conductivity is arranged in parallel to resistor Rtsh and controlled by a modulation signal DYHY_H, and a bypass transistor 908 (e.g., an n-channel MOS transistor) having a tunable conductivity is arranged in parallel to resistor Rtdl and controlled by a modulation signal DYHY_L. A first shaping circuit 92 is coupled to the output of comparator 84 and is configured to produce signal DYHY_H so that, in response to assertion (e.g., a rising edge) of signal Reg_sw, the modulation signal DYHY_H abruptly passes from the asserted state to the de-asserted state to turn off transistor 906, and subsequently gradually (e.g., smoothly) passes again from the de-asserted to the asserted state to gradually increase the conductivity of transistor 906. Thus, when signal Reg_sw switches to the asserted state, transistor 906 turns off abruptly and subsequently turns on gradually, so that the resistance Rtsh′ between nodes 924 and 932 passes abruptly from a negligible value (around zero) to Rtsh and then gradually decays towards zero again. Therefore, the high dynamic threshold V_{T,H_D} at node 932 is normally equal to the high static threshold V_{T,H_S} (V_{T,H_S}=V_{ref}+I_{bias}*Rtdh), is abruptly set to the maximum value V_{T,H_MAX} in response to assertion of signal Reg_sw (V_{T,H_MAX}=V_{ref}+I_{bias}*(Rtdh+Rtsh)), and then decays again towards V_{T,H_S}. Similarly, a second shaping circuit 94 is coupled to the output of comparator 84 and is configured to produce signal DYHY_L so that, in response to de-assertion (e.g., a falling edge) of signal Reg_sw, the modulation signal DYHY_L abruptly passes from the asserted state to the de-asserted state to turn off transistor 908, and subsequently gradually (e.g., smoothly) passes again from the de-asserted to the asserted state to gradually increase the conductivity of transistor 908. Thus, when signal Reg_sw switches to the de-asserted state, transistor 908 turns off abruptly and subsequently turns on gradually, so that the resistance Rtdl′ between nodes 944 and 952 passes abruptly from a negligible value (around zero) to Rtdl and then gradually decays towards zero again. Therefore, the low dynamic threshold V_{T,L_D} at node 952 is normally equal to the low static threshold V_{T,L_S}(V_{T,L_S}=V_{ref}−I_{bias}*Rtsl), is abruptly set to the minimum value V_{T,L_MIN} in response to de-assertion of signal Reg_sw (V_{T,L_MIN}=V_{ref}−I_{bias}*(Rtsl+Rtdl)), and then decays again towards V_{T,L_S}.

Therefore substantially, in the architecture of FIG. 9, the static thresholds (V_{T,H_S} and V_{T,L_S}) are produced by adding/subtracting a fixed R*I contribution (Rtdh*I_{bias} and Rtsl*I_{bias}, respectively) to/from the reference voltage Vᵣg. The dynamic thresholds (V_{T,H_D} and V_{T,L_D}) are produced by adding/subtracting a temporary R*I contribution, given by time-variable resistances. The resistance modulation is obtained, at both sides, bypassing the resistors (Rtsh and Rtdl, respectively) that produce the maximum/minimum values (V_{T,H_MAX} and V_{T,L_MIN}, respectively) with respective transistors (e.g., n-channel MOS transistors) whose conductance is modulated from zero (fully off) to a maximum value able to effectively bypass the respective resistor (i.e., where the resistance of the bypassing transistors is negligible compared to the resistance of the bypassed resistors) by a smooth gate voltage driving (i.e., signals DYHY_H and DYHY_L). Differently from the scheme of FIG. 8, the maximum and minimum values V_{T,H_MAX} and V_{T,L_MIN} are here created “in real time” (e.g., in few nanoseconds) as soon the respective threshold is selected. The modulation signals DYHY_H and DYHY_L are generated once an associated variation of the sensor output (e.g., a commutation of signal Reg_sw) is detected. The waveforms of signals in the circuit architecture of FIG. 8 are illustrated in the diagram of FIG. 10, which differs from the diagram of FIG. 7 in the shape of the dynamic thresholds V_{T,H_D} and V_{T,L_D}.

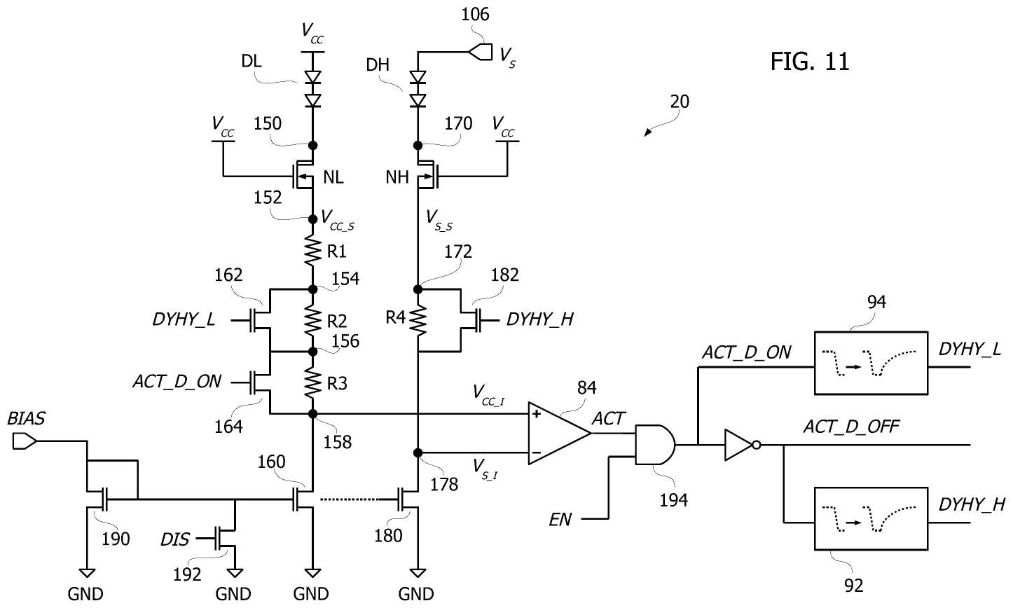

It is noted that a dynamic hysteresis operation similar to that of the circuits of FIGS. 8 and 9 may be obtained, in some embodiments, by modulating both input signals of the comparator 84, instead of modulating two different threshold signals. For instance, FIG. 11 is a circuit diagram exemplary of one or more embodiments where the dynamic hysteresis operating principle is applied to the active diode driver 60 of a bootstrap path of a half-bridge driver (similar to that of FIG. 2) applying modulation to voltage V_{CC} (which is used in place of the reference voltage V_{ref}) to produce the low dynamic threshold and to voltage V_{S} (which corresponds to the regulated voltage V_{reg}) to emulate the high dynamic threshold effect.

In particular, the active diode regulation sensor 20 of FIG. 11 includes a first current flow line arranged between the supply terminal 100a (to receive voltage V_{CC}) and ground GND. The first current flow line includes the following components arranged in series: a set of series-connected diodes DL (e.g., two diodes) arranged to be conductive from node 100a to a node 150, a decoupling transistor NL (e.g., an n-channel MOS high-voltage transistor) having a conductive channel arranged between node 150 and node 152 and a control (e.g., gate) terminal coupled to the sensor supply voltage V_{CC}, a resistor R1 (e.g., 2 kΩ) arranged between nodes 152 and 154, a resistor R2 (e.g., 24 kΩ) arranged between nodes 154 and 156, a resistor R3 (e.g., 4 kΩ) arranged between nodes 156 and 158, and a current generator 160 coupled between node 158 and ground GND to sink a bias current I_{bias} (e.g., 23 μA). Additionally, a bypass transistor 162 (e.g., an n-channel MOS transistor) having a tunable conductivity is arranged in parallel to resistor R2 and controlled by the modulation signal DYHY_L, and a bypass transistor 164 (e.g., an n-channel MOS transistor) operating as an on/off switch is arranged in parallel to resistor R3 and controlled by the activation signal ACT_D_ON. A voltage V_{CC} r is thus produced at node 158.

The active diode regulation sensor 20 of FIG. 11 includes a second current flow line arranged between the intermediate supply node 106 (to receive voltage V_{S}) and ground GND. The second current flow line includes the following components arranged in series: a set of series-connected diodes DH (e.g., two diodes) arranged to be conductive from node 106 to a node 170, a decoupling transistor NH (e.g., an n-channel MOS high-voltage transistor) having a conductive channel arranged between node 170 and node 172 and a control (e.g., gate) terminal coupled to the sensor supply voltage V_{CC}, a resistor R4 (e.g., 8 kΩ) arranged between nodes 172 and 178, and a current generator 180 coupled between node 178 and ground GND to sink a bias current I_{bias} (e.g., 23 μA). Additionally, a bypass transistor 182 (e.g., an n-channel MOS transistor) having a tunable conductivity is arranged in parallel to resistor R4 and controlled by the modulation signal DYHY_H. A voltage V_{S_I} is thus produced at node 178.

As exemplified in FIG. 11, the current generators 160 and 180 may be implemented as current mirrors. Thus, the sensor 20 may include a diode-connected transistor 190 (e.g., an n-channel MOS transistor) having a conductive channel arranged between a bias source BIAS and ground GND, a transistor 160 (e.g., an n-channel MOS transistor) having a conductive channel arranged between node 158 and ground GND, and a transistor 180 (e.g., an n-channel MOS transistor) having a conductive channel arranged between node 178 and ground GND, where the control (e.g., gate) terminals of transistors 160 and 180 are coupled to the control (e.g., gate) terminal of transistor 190. Further, a pull-down transistor 192 may have a conductive channel arranged between the control terminals of transistors 160, 180 and ground and may be controlled by a disable signal DIS. The disable signal DIS may be asserted (e.g., high) if the low-side switch LS of the half-bridge is off, and may be de-asserted (e.g., low) if the low-side switch LS of the half-bridge is on, so that the sensor circuit 20 is functional (only) when the low-side switch LS is on. Signal DIS may thus substantially correspond to the complement of the low-side gate control signal LVG.

As exemplified in FIG. 11, the comparator 84 (or 22) has a first (e.g., positive) terminal coupled to node 158 and a second (e.g., negative) terminal coupled to node 178 to compare signals V_{CC_1} and V_{S_1} and produce an activation signal ACT. The activation signal ACT is gated by an enable signal EN at an AND logic gate 194 to produce the activation signal ACT_D_ON for the active diode Q3 (only) when the low-side switch LS is on. Signal EN may thus substantially correspond to the low-side gate control signal LVG (and to the complement of signal DIS). Shaping circuits 92 and 94 operate substantially as discussed with reference to FIGS. 9 and 10, that is: produce a signal DYHY_H that gradually passes from the de-asserted state to the asserted state in response to assertion (e.g., a rising edge) of signal ACT_D_ON (or equivalently, in response to de-assertion of the complement ACT_D_OFF of signal ACT_D_ON), and produce a signal DYHY_L that gradually passes from the de-asserted state to the asserted state in response to de-assertion (e.g., a falling edge) of signal ACT_D_ON. By way of example, the smooth transition of signal DYHY_H may last about 2 μs and the smooth transition of signal DYHY_L may last about 50 ns.

It is noted that the active diode regulation sensor 20 is drain-driven (i.e., takes input signals at nodes 150 and 170 that are the drain terminals of transistors NL and NH) insofar as one of the input signals (specifically, V_{S}) can be biased at a high voltage and the MOS technology allows decoupling a low voltage from a high voltage (only) via the drain. The decoupling transistors NL, NH are “pseudo-cascode” high-voltage n-channel MOS transistors, that are able to separate the internal nodes from the input nodes (in particular, node 106) when the latter is in the high-voltage phase.

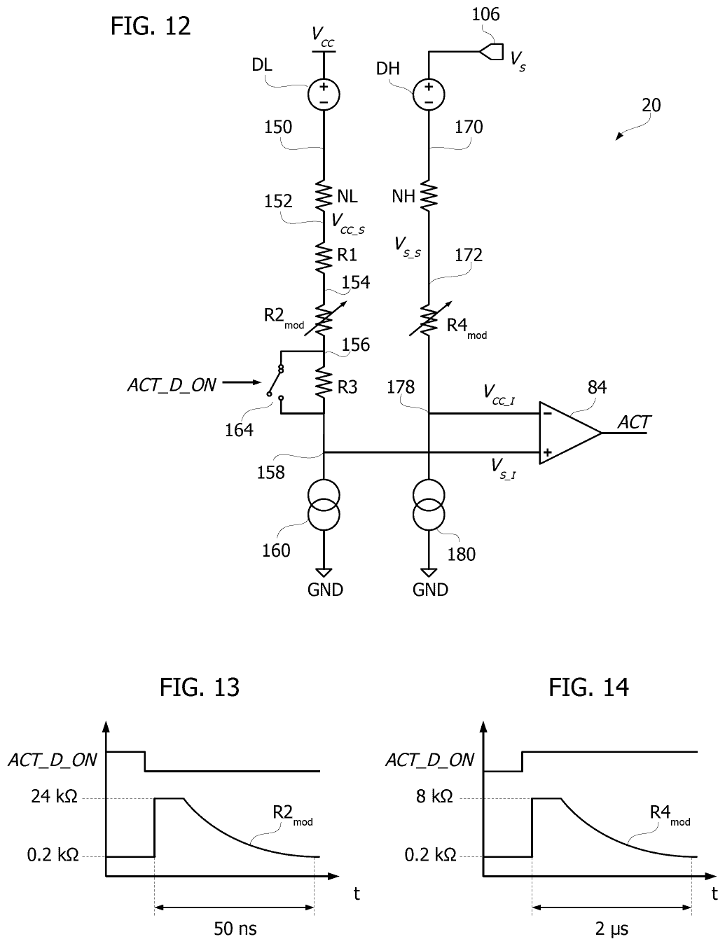

FIG. 12 is a circuit diagram exemplary of small-signal operation of the voltage sensor 20 of FIG. 11. In the first current flow line, the diodes DL provide a fixed voltage drop of about 2*V_{BE}, transistor NL provides a resistance R_{NL}=k*(V_{CC}−V_{CC_S}−Vₜₕ) where V_{CC_S} is the voltage at node 152, resistor R2 with transistor 162 provide a variable resistance R2_{mod} (e.g., variable between about 24 kΩ and about 0.2 kΩ), and resistor R3 with transistor 164 provide a fixed resistance that can be bypassed. In the second current flow line, the diodes DH provide a fixed voltage drop of about 2*V_{BE}, transistor NH provides a resistance R_{NH}=k*(V_{S}−V_{SS}−Vₜₕ) where V_{S_S} is the voltage at node 172, resistor R4 with transistor 182 provide a variable resistance R4_{mod} (e.g., variable between about 8 kΩ and about 0.2 kΩ). FIG. 13 is a time diagram exemplary of the possible variation of resistance R2_{mod} in response to a falling edge of signal ACT_D_ON, and FIG. 14 is a time diagram exemplary of the possible variation of resistance R4_{mod} in response to a rising edge of signal ACT_D_ON.

Therefore, the second current flow line (“bootstrap side” or “high side”) behaves as a voltage shifter, where the high-voltage decoupler NH works in linear mode once the input voltage V_{S} is close to the trigger point. The linear mode operation is set by the series diodes DH, which lower the drain voltage of transistor NH enough to exit the saturation mode. The voltage shifting is operated by the biasing current I_{bias} (e.g., generated by saturated n-channel MOS transistor 180) via a series of resistors that can be bypassed or time modulated. A similar voltage shifter is provided by the first current low line (“reference side”), whose input voltage is the sensor supply voltage V_{CC}. The static and dynamic hysteresis is obtained via a separated modulation of the total resistance encountered by the current flow in each voltage shifter.

In the example of FIGS. 11 and 12, applicable as discussed with reference to FIG. 2, the values of the static and dynamic thresholds may be set according to certain design rules discussed in the following.

In particular, the static high threshold V_{T,H_S} may be set to V_{CC} to maximize the advantages of adopting an active diode Q3, but there might be reasons to set it slightly below voltage V_{CC}. A first reason is that despite the drain-source on-resistance of the active diode Q3 can be very low (e.g., few Ohms), voltage V_{S} will practically never reach the value of the sensor supply voltage V_{CC}, insofar as there is some current consumption related to node 106 (e.g., due to the driver 62 of the current limiter Q1′, to the leakage bypassing the current limiter Q1′, etc.). A second reason is that, if aiming at V_{T,H_S}=V_{CC}, the static high threshold V_{T,H_S} could be accidentally set over the sensor supply voltage V_{CC} because of the mismatch of some parameters of the components of the two voltage shifters in the voltage sensor 20 or in the comparator 84. In some applications, this may result in a small but possibly detrimental “backwash current” that affects the regulation of the bootstrap voltage V_{BO}. Such a potential mismatch can thus be compensated by introducing an opposite mismatch, resulting in the static high threshold V_{T,H_S} being slightly lower than voltage V_{CC}. For instance, in a particular example the static high threshold V_{T,H_S} may be set to a value equal to V_{CC}−46 mV, since the hysteresis resistors R2, R3 and R4 are bypassed (providing a low resistance of about 100Ω to the current flow) and the working resistor R1 has a resistance of about 2 kΩ, so that the voltage mismatch created at the differential output of the V_{CC} and V_{S} shifters (i.e., V_{CC_1} vs. V_{S_1}) is equal to 23 μA*2 kΩ 46 mV. On the other hand, the static low threshold V_{T,L_S} may be the one selected at the sensor enable, and its value may be set by the “working resistor configuration”, that is: V_{T,L_S}=V_{CC}−(2+4)kΩ*23 μA=V_{CC}−138 mV. The resulting static hysteresis width (i.e., V_{T,H_S}−V_{T,L_S}) may thus be about 90 mV, sufficient to filter the noise in typical semiconductor devices (e.g., thermal, flicker, RTS noise).

Concerning the dynamic thresholds, the maximum value V_{T,H_MAX} of the dynamic high threshold may be set to V_{CC}+138 mV, while the decay time may be set to about 2 μs. This setting may directly impact the trade-off between the desire of limiting the occurrence of the on/off oscillating regime and the desire of limiting the backwash current. In fact, the maximum value V_{T,H_MAX} of the dynamic high threshold (given by V_{CC}+(8−2)kΩ*23 μA) may be set above any estimated overshoot (e.g., within the 6-sigma statistics) of signal V_{S} consequent to the switch-on transition of the active diode Q3 (e.g., from about V_{CC} to about 2*V_{CC}), possibly resulting in an acceptable backwash current (which occurs when V_{CC}<V_{S}<V_{T,H} and the current limiter Q1′ is switched on). The decay time may be set as a compromise between two parameters representative of the previously mentioned contrasting requirements, i.e., the current consumption due to the controlled on/off regime and the drop of the bootstrap voltage V_{BO} due to the temporary backwash current. For instance, the current I_{cc} related to the controlled on/off oscillation may be about 80 μA in a typical case. The drop of the bootstrap voltage V_{BO} due to the backwash current may be evaluated in a worse case (as discussed in more detail in the following), which may result in an acceptable value (e.g., about 140 mV) considering a capacitance of about 100 nF for the bootstrap capacitor C_{B}. On the other hand, the minimum value V_{T,L_MIN} of the dynamic low threshold may be set to V_{CC}−690 mV by the “working resistance configuration” (where V_{T,L_MIN}=V_{CC}−(2+4+24)kΩ*23 μA=V_{CC}−690 mV) while the decay time may be set to about 50 ns.

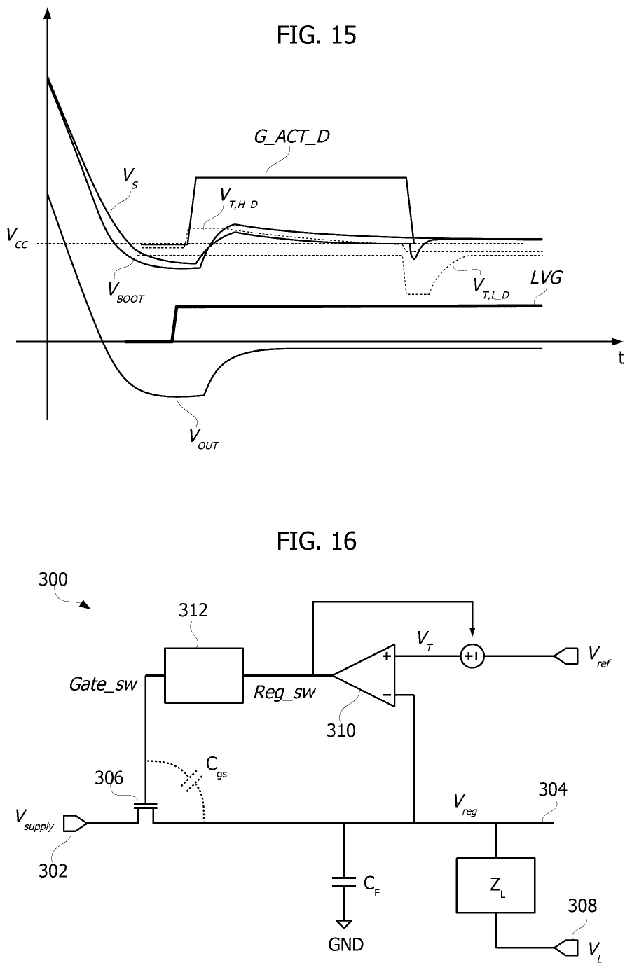

FIG. 15 is a diagram including possible waveforms of signals in the architecture of FIGS. 1 and 2 where an active diode regulation sensor 20 as exemplified in FIG. 11 is implemented, in particular: the sensor supply voltage V_{CC} (dotted line), the threshold voltages V_{T,H_D} and V_{T,L_D} (dotted lines), the intermediate supply voltage V_{S} at node 106 (solid line), the floating supply voltage V_{BOOT} at node 104 (solid line), the output voltage V_{OUT} at the switching node 102a (solid line), the low-side gate control signal LVG (solid line), and the diode control signal G_ACT_D (solid line). The waveforms of FIG. 15 show that use of a voltage sensor 20 with dynamic hysteresis to regulate the voltage V_{S} at node 106 may effectively limit the backwash current to an acceptable amount, setting a dynamic control of such undesired event. For instance, in a theoretically possible worst case where the current limiter Q1′ is on, the waveform of voltage V_{S} runs slightly below the waveform of the high threshold V_{T,H}, the wasted charge may be estimated assuming that the on-resistance (Rds) of the active diode Q3 may be about 10Ω and that the decay of signals V_{T,H} and V_{S} is linear. Under these assumptions, the charge wasted during the phase when V_{BOOT}>V_{S}>V_{CC} can thus be estimated as:

$$( {V}_{T , H \_ MAX} - {V}_{C C} ) * {T}_{decay} / ( 2 * Rds ) = 138 mV * 2 μs / 20 Ω \sim 14 nC$$

In case the capacitance of the bootstrap capacitor C_{B} is about 100 nF, such wasted charge may thus result in a reduction of the bootstrap voltage V_{BO} of about 140 mV.

As previously discussed, one or more embodiments may be applicable not only to half-bridge drivers with high-side bootstrap architecture, but generally to any switching (on/off) voltage regulator with hysteresis that is possibly affected by the gate feedthrough issue. FIG. 16 is a circuit block diagram exemplary of such a switching regulator 300, which includes an input node 302 for receiving an input supply voltage V_{supply}, an output node 304 for producing a regulated voltage V_{reg}, a pass element 306 (on/off switch) arranged between nodes 302 and 304 (e.g., a MOS transistor) and controlled by signal Gate_sw (where the pass element 306 has a parasitic capacitive coupling C_{gs} between the output terminal and the control terminal), a filter capacitor C_{F} arranged between the output node 304 and ground GND, a load Z_{L} arranged between the output node 304 and a voltage reference node 308 at voltage V_{L}, a comparator 310 configured to compare with hysteresis voltage V_{reg} to a dynamic threshold V_{T} produced from a reference voltage V_{ref}, and a gate driver 312 configured to produce signal Gate_sw as a function of the outcome of the comparison operated by comparator 310.

In the generic example of FIG. 16, the ratio between the filtering capacitance C_{F} and the parasitic capacitive coupling C_{gs} is crucial in the onset of the same issues previously discussed with reference to the bootstrap path circuitry of a half-bridge driver, i.e., the possible onset of an undesired high-frequency on/off oscillating regime or of undesired backwash current. For instance, the on/off oscillating regime may be triggered when the following condition is satisfied: DV_{Gate}*C_{gs}/(C_{F}+C_{gs})>DV_{threshold}, where DV_{Gate} is the dynamics of signal Gate_sw and DV_{threshold} is the width of the hysteresis of comparator 310. The dynamic hysteresis can thus be a solution when an adequate (e.g., large enough) filter capacitor cannot be implemented.

One or more embodiments may thus provide a time modulation of the voltage thresholds in an on/off regulation with hysteresis. The purpose is to temporarily enlarge the hysteresis width to include the noise peaks of the regulated signal within the hysteresis range, such as to inhibit the excessive negative feedback that could lead to uncontrolled on/off oscillating regime. The thresholds can be time-modulated by adding a voltage contribution to each (or only one) baseline threshold level (also referred to as static thresholds) when such a threshold is selected. The additional voltage contribution can then decay to zero, e.g., due to an RC discharge or any equivalent circuit inside a dedicated threshold control circuit, so that the dynamic threshold asymptotically approaches the static level.

One or more embodiments as exemplified herein may thus provide a satisfying compromise between the requirement of regulation precision, insofar as the width of the static hysteresis (i.e., the difference between the static or baseline thresholds V_{T,H_S} and V_{T,L_S}) is rather limited, and the requirements of noise and power consumption, insofar as the coupling noise is absorbed and the ripple of the regulated voltage is controlled both as voltage and frequency.

Without prejudice to the underlying principles, the details and embodiments may vary, even significantly, with respect to what has been described by way of example, without departing from the extent of protection.

The extent of protection is determined by the annexed claims.

A voltage regulator circuit (300) may be summarized as including: an input node (302; 100a) configured to receive an input supply voltage (V_{supply}; V_{CC}); an output node (304; 106) configured to produce an output regulated voltage (V_{reg}; V_{S}); a switchable pass element (306; Q3) having a selectively conductive channel arranged between said input node (302) and said output node (304); and a comparator circuit (310; 84) configured to compare said output regulated voltage (V_{reg}) to a dynamic threshold (V_{T}) to produce a control signal (Reg_sw; ACT) to control switching of said switchable pass element (306), wherein said control signal being asserted results in said switchable pass element (306) being turned on, and said control signal being de-asserted results in said switchable pass element (306) being turned off; wherein the voltage regulator circuit (300) further comprises a threshold selection and shaping circuit (82; 20) configured to shape said output regulated voltage and/or said dynamic threshold so that: in response to assertion of said control signal (Reg_sw), the difference between said dynamic threshold (V_{T}) and said output regulated voltage (V_{reg}) is abruptly increased and subsequently gradually decreased towards a target static value; and in response to de-assertion of said control signal (Reg_sw), the difference between said output regulated voltage (V_{reg}) and said dynamic threshold (V_{T}) is abruptly increased and subsequently gradually decreased towards a target static value.

Said threshold selection and shaping circuit (82) may include: a reference node (820) configured to receive a reference voltage (V_{ref}); a first circuit arrangement configured to add a first fixed voltage to said reference voltage (V_{ref}) to produce an upper static threshold (V_{T,H_S}); a second circuit arrangement configured to add a first variable voltage to said upper static threshold (V_{T,H_S}) to produce an upper dynamic threshold (V_{T,H_D}); a third circuit arrangement configured to subtract a second fixed voltage from said reference voltage (V_{ref}) to produce a lower static threshold (V_{T,L_S}); a fourth circuit arrangement configured to subtract a second variable voltage from said lower static threshold (V_{T,L_S}) to produce a lower dynamic threshold (V_{T,L_D}); wherein said first variable voltage may be gradually decreased in response to assertion of said control signal (Reg_sw) and said second variable voltage may be gradually decreased in response to de-assertion of said control signal (Reg_sw); and wherein the threshold selection and shaping circuit (82) may further include a switch (860) configured to produce said dynamic threshold (V_{T}) received at said comparator circuit (84) by propagating said upper dynamic threshold (V_{T,H_D}) in response to assertion of said control signal (Reg_sw) and propagating said lower dynamic threshold (V_{T,L_D}) in response to de-assertion of said control signal (Reg_sw).

Said first circuit arrangement may include a first voltage generator (822) coupled between said reference node (820) and a first static node (824) to produce said upper static threshold (V_{T,H_S}) at said first static node (824); said second circuit arrangement may include a second voltage generator (826) and a first selectively activatable RC discharge circuit (R_{H}, C_{H}) coupled in parallel between said first static node (824) and a first dynamic node (832), wherein said first dynamic node (832) is coupled to said second voltage generator (826) in response to said control signal (Reg_sw) being de-asserted and coupled to said first RC discharge circuit (R_{H}, C_{H}) in response to said control signal (Reg_sw) being asserted, to produce said upper dynamic threshold (V_{T,H_D}) at said first dynamic node (832); said third circuit arrangement may include a third voltage generator (842) coupled between said reference node (820) and a second static node (844) to produce said lower static threshold (V_{T,L_S}) at said second static node (844); said fourth circuit arrangement may include a fourth voltage generator (846) and a second selectively activatable RC discharge circuit (R_{L}, C_{L}) coupled in parallel between said second static node (844) and a second dynamic node (852), wherein said second dynamic node (852) is coupled to said fourth voltage generator (846) in response to said control signal (Reg_sw) being asserted and coupled to said second RC discharge circuit (R_{L}, C_{L}) in response to said control signal (Reg_sw) being de-asserted, to produce said lower dynamic threshold (V_{T,L_D}) at said second dynamic node (852).

Said threshold selection and shaping circuit (82) may include a current flow line between said supply voltage (V_{supply}) and ground (GND), and wherein: said first circuit arrangement may include a first resistor (Rtdh) arranged in said current flow line between said reference node (820) and a first static node (924) to produce said upper static threshold (V_{T,H_S}) at said first static node (924); said second circuit arrangement may include a second resistor (Rtsh) and a first bypass transistor (906) arranged in parallel in said current flow line between said first static node (924) and a first dynamic node (932), wherein the conductivity of said first bypass transistor (906) may be gradually increased in response to assertion of said control signal (Reg_sw), to produce said upper dynamic threshold (V_{T,H_D}) at said first dynamic node (932); said third circuit arrangement may include a third resistor (Rtsl) arranged in said current flow line between said reference node (820) and a second static node (944) to produce said lower static threshold (V_{T,L_S}) at said second static node (944); said fourth circuit arrangement may include a fourth resistor (Rtdl) and a second bypass transistor (908) arranged in parallel in said current flow line between said second static node (944) and a second dynamic node (952), wherein the conductivity of said second bypass transistor (908) may be gradually increased in response to de-assertion of said control signal (Reg_sw), to produce said lower dynamic threshold (V_{T,L_D}) at said second dynamic node (952).

At steady state the conductivity of said first bypass transistor (906) and of said second bypass transistor (908) may be high.

Said threshold selection and shaping circuit (20) may include: a first circuit arrangement configured to subtract a first fixed voltage from said input supply voltage (V_{CC}) to produce a static threshold (V_{CC_S}); a second circuit arrangement configured to subtract a first variable voltage from said static threshold (V_{CC_S}) to produce a dynamic threshold (V_{CC_I}); a third circuit arrangement configured to subtract a second fixed voltage from said output regulated voltage (V_{S}) to produce a static comparison signal (V_{S_S}); a fourth circuit arrangement configured to subtract a second variable voltage from said static comparison signal (V_{S_S}) to produce a dynamic comparison signal (V_{S_I}); wherein said first variable voltage may be gradually decreased in response to de-assertion of said control signal (ACT) and said second variable voltage is gradually decreased in response to assertion of said control signal (ACT); wherein said comparator circuit (84) may be configured to compare said dynamic threshold (V_{CC_I}) to said dynamic comparison signal (V_{S_I}) to produce said control signal (ACT).

Said first circuit arrangement may include a first set of diodes (DL) coupled in series to a first decoupling transistor (NL) between said input node and a first static node (152, 154) to produce said static threshold (V_{CC_S}) at said first static node (152, 154); said second circuit arrangement may include a first resistor (R2) and a first modulation transistor (162) coupled in parallel between said first static node (152, 154) and a first dynamic node (156, 158), wherein the conductivity of said first modulation transistor (162) may be gradually increased in response to a falling edge of said control signal (ACT) to produce said dynamic threshold (V_{CC_I}) at said first dynamic node (156, 158); said third circuit arrangement may include a second set of diodes (DH) coupled in series to a second decoupling transistor (NH) between said output node (106) and a second static node (172) to produce said static comparison signal (V_{S_S}) at said second static node (172); said fourth circuit arrangement may include a second resistor (R4) and a second modulation transistor (182) coupled in parallel between said second static node (172) and a second dynamic node (178), wherein the conductivity of said second modulation transistor (182) may be gradually increased in response to a rising edge of said control signal (ACT) to produce said comparison signal (V_{S} r) at said second dynamic node (178).

Said threshold selection and shaping circuit (20) may further include a third resistor (R3) and a bypass transistor (164) coupled in parallel between said first dynamic node (156) and the input of said comparator circuit (84), wherein the bypass transistor (164) may be fully turned on in response to said control signal (ACT) being asserted and may be fully turned off in response to said control signal (ACT) being de-asserted.

A half-bridge driver circuit (HBD), may be summarized as including: a positive supply pin (100a) and a ground pin (100b, 102b) configured to receive therebetween a power supply voltage (V_{CC}); a first control pin configured to receive a low-voltage high-side control signal (IN_{HS}) for controlling a high-side switch (HS) of a half-bridge circuit; a second control pin configured to receive a low-voltage low-side control signal (IN_{LS}) for controlling a low-side switch (LS) of said half-bridge circuit; a high-side gate driver circuit (12a) configured to receive said low-voltage high-side control signal (IN_{HS}) via a level shifter circuit (14) and produce a respective high-side gate control signal (HVG); a low-side gate driver circuit (12b) configured to receive said low-voltage low-side control signal (IN_{LS}) and produce a respective low-side gate control signal (LVG); wherein said high-side gate driver circuit (12a) is biased between a floating supply pin (104) and a switching pin (102a) of the half-bridge driver circuit (HBD), and wherein said floating supply pin (104) is coupled to said positive supply pin (100a) via a bootstrap path that includes: a voltage regulator circuit (300) that may include an input node (302; 100a) configured to receive an input supply voltage (V_{supply}; V_{CC}); an output node (304; 106) configured to produce an output regulated voltage (V_{reg}; V_{S}); a switchable pass element (306; Q3) having a selectively conductive channel arranged between said input node (302) and said output node (304); and a comparator circuit (310; 84) configured to compare said output regulated voltage (V_{reg}) to a dynamic threshold (V_{T}) to produce a control signal (Reg_sw; ACT) to control switching of said switchable pass element (306), wherein said control signal being asserted results in said switchable pass element (306) being turned on, and said control signal being de-asserted results in said switchable pass element (306) being turned off; wherein the voltage regulator circuit (300) further comprises a threshold selection and shaping circuit (82; 20) configured to shape said output regulated voltage and/or said dynamic threshold so that: in response to assertion of said control signal (Reg_sw), the difference between said dynamic threshold (V_{T}) and said output regulated voltage (V_{reg}) is abruptly increased and subsequently gradually decreased towards a target static value; and in response to de-assertion of said control signal (Reg_sw), the difference between said output regulated voltage (V_{reg}) and said dynamic threshold (V_{T}) is abruptly increased and subsequently gradually decreased towards a target static value, the voltage regulator circuit (300) having its input node connected to said positive supply pin (100a) and its output node connected to a decoupling node (106) internal to the half-bridge driver circuit (HBD); and a current limiter circuit (Q1′) arranged between said decoupling node (106) and said floating supply pin (104).

An electronic device, may be summarized as including: a half-bridge driver circuit (HBD) that may include a positive supply pin (100a) and a ground pin (100b, 102b) configured to receive therebetween a power supply voltage (V_{CC}); a first control pin configured to receive a low-voltage high-side control signal (IN_{HS}) for controlling a high-side switch (HS) of a half-bridge circuit; a second control pin configured to receive a low-voltage low-side control signal (IN_{LS}) for controlling a low-side switch (LS) of said half-bridge circuit; a high-side gate driver circuit (12a) configured to receive said low-voltage high-side control signal (IN_{HS}) via a level shifter circuit (14) and produce a respective high-side gate control signal (HVG); a low-side gate driver circuit (12b) configured to receive said low-voltage low-side control signal (IN_{LS}) and produce a respective low-side gate control signal (LVG); wherein said high-side gate driver circuit (12a) is biased between a floating supply pin (104) and a switching pin (102a) of the half-bridge driver circuit (HBD), and wherein said floating supply pin (104) is coupled to said positive supply pin (100a) via a bootstrap path that includes: a voltage regulator circuit (300), the voltage regulator circuit (300) having its input node connected to said positive supply pin (100a) and its output node connected to a decoupling node (106) internal to the half-bridge driver circuit (HBD); and a current limiter circuit (Q1′) arranged between said decoupling node (106) and said floating supply pin (104); a high-side switch (HS) coupled between a positive bus pin (108) and said switching pin (102a) of the half-bridge driver circuit (HBD); a low-side switch (LS) coupled between said switching pin (102a) of the half-bridge driver circuit (HBD) and said ground pin (100b, 102b); and a bootstrap capacitor (C_{B}) coupled between said floating supply pin (104) and said switching pin (102a) of the half-bridge driver circuit (HBD).

A method of operating a voltage regulator circuit (300) may be summarized as including: receiving an input supply voltage (V_{supply}; V_{CC}) at said input node (302; 100a); producing an output regulated voltage (V_{reg}; V_{S}) at said output node (304; 106); comparing said output regulated voltage (V_{reg}) to a dynamic threshold (V_{T}) at said comparator circuit (310; 84) to produce a control signal (Reg_sw; ACT) to control switching of said switchable pass element (306), turning on said switchable pass element (306) in response to said control signal being asserted, and turning off said switchable pass element (306) in response to said control signal being de-asserted; and shaping said output regulated voltage and/or said dynamic threshold at said threshold selection and shaping circuit (82; 20), abruptly increasing and subsequently gradually decreasing towards a target static value the difference between said dynamic threshold (V_{T}) and said output regulated voltage (V_{reg}) in response to assertion of said control signal (Reg_sw), and abruptly increasing and subsequently gradually decreasing towards a target static value the difference between said output regulated voltage (V_{reg}) and said dynamic threshold (V_{T}) in response to de-assertion of said control signal (Reg_sw).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A voltage regulator circuit, comprising:
an input node configured to receive an input supply voltage;
an output node configured to output an output regulated voltage;
a switchable pass element having a selectively conductive channel arranged between the input node and the output node;
a comparator circuit configured to compare the output regulated voltage to a dynamic threshold to produce a control signal to control switching of the switchable pass element, wherein the control signal being asserted results in the switchable pass element being turned on, and the control signal being de-asserted results in the switchable pass element being turned off; and
a threshold selection and shaping circuit configured to shape the output regulated voltage or the dynamic threshold so that:
in response to assertion of the control signal, a difference between the dynamic threshold and the output regulated voltage is increased and subsequently gradually decreased towards a target static value; and
in response to de-assertion of the control signal, the difference between the output regulated voltage and the dynamic threshold is increased and subsequently gradually decreased towards the target static value.

2. The voltage regulator circuit according to claim 1, wherein the threshold selection and shaping circuit includes:
a reference node configured to receive a reference voltage;
a first circuit arrangement configured to add a first fixed voltage to the reference voltage to produce an upper static threshold;
a second circuit arrangement configured to add a first variable voltage to the upper static threshold to produce an upper dynamic threshold;
a third circuit arrangement configured to subtract a second fixed voltage from the reference voltage to produce a lower static threshold;
a fourth circuit arrangement configured to subtract a second variable voltage from the lower static threshold to produce a lower dynamic threshold,
wherein the first variable voltage is gradually decreased in response to assertion of the control signal and the second variable voltage is gradually decreased in response to de-assertion of the control signal; and
a switch configured to produce the dynamic threshold received at the comparator circuit by propagating the upper dynamic threshold in response to assertion of the control signal and propagating the lower dynamic threshold in response to de-assertion of the control signal.

3. The voltage regulator circuit according to claim 2, wherein:
the first circuit arrangement includes a first voltage generator coupled between the reference node and a first static node to produce the upper static threshold at the first static node,
the second circuit arrangement includes a second voltage generator and a first selectively activatable RC discharge circuit coupled in parallel between the first static node and a first dynamic node, wherein the first dynamic node is coupled to the second voltage generator in response to the control signal being de-asserted and coupled to the first RC discharge circuit in response to the control signal being asserted, to produce the upper dynamic threshold at the first dynamic node,
the third circuit arrangement includes a third voltage generator coupled between the reference node and a second static node to produce the lower static threshold at the second static node, and
the fourth circuit arrangement includes a fourth voltage generator and a second selectively activatable RC discharge circuit coupled in parallel between the second static node and a second dynamic node, wherein the second dynamic node is coupled to the fourth voltage generator in response to the control signal being asserted and coupled to the second RC discharge circuit in response to the control signal being de-asserted, to produce the lower dynamic threshold at the second dynamic node.

4. The voltage regulator circuit according to claim 2, wherein the threshold selection and shaping circuit comprises a current flow line between the input supply voltage and ground, and wherein:
the first circuit arrangement includes a first resistor arranged in the current flow line between the reference node and a first static node to produce the upper static threshold at the first static node,
the second circuit arrangement includes a second resistor and a first bypass transistor arranged in parallel in the current flow line between the first static node and a first dynamic node, wherein a conductivity of the first bypass transistor is gradually increased in response to assertion of the control signal, to produce the upper dynamic threshold at the first dynamic node,
the third circuit arrangement includes a third resistor arranged in the current flow line between the reference node and a second static node to produce the lower static threshold at the second static node, and
the fourth circuit arrangement includes a fourth resistor and a second bypass transistor arranged in parallel in the current flow line between the second static node and a second dynamic node, wherein a conductivity of the second bypass transistor is gradually increased in response to de-assertion of the control signal, to produce the lower dynamic threshold at the second dynamic node.

5. The voltage regulator circuit according to claim 4, wherein at steady state the conductivity of the first bypass transistor and of the second bypass transistor is high.

6. The voltage regulator circuit according to claim 1, wherein the threshold selection and shaping circuit includes:
a first circuit arrangement configured to subtract a first fixed voltage from the input supply voltage to produce a static threshold;
a second circuit arrangement configured to subtract a first variable voltage from the static threshold to produce the dynamic threshold;
a third circuit arrangement configured to subtract a second fixed voltage from the output regulated voltage to produce a static comparison signal; and
a fourth circuit arrangement configured to subtract a second variable voltage from the static comparison signal to produce a dynamic comparison signal,
wherein the first variable voltage is gradually decreased in response to de-assertion of the control signal and the second variable voltage is gradually decreased in response to assertion of the control signal, and
wherein the comparator circuit is configured to compare the dynamic threshold to the dynamic comparison signal to produce the control signal.

7. The voltage regulator circuit according to claim 6, wherein:
the first circuit arrangement includes a first set of diodes coupled in series to a first decoupling transistor between the input node and a first static node to produce the static threshold at the first static node,
the second circuit arrangement includes a first resistor and a first modulation transistor coupled in parallel between the first static node and a first dynamic node, wherein a conductivity of the first modulation transistor is gradually increased in response to a falling edge of the control signal to produce the dynamic threshold at the first dynamic node,
the third circuit arrangement includes a second set of diodes coupled in series to a second decoupling transistor between the output node and a second static node to produce the static comparison signal at the second static node, and
the fourth circuit arrangement comprises a second resistor and a second modulation transistor coupled in parallel between the second static node and a second dynamic node, wherein a conductivity of the second modulation transistor is gradually increased in response to a rising edge of the control signal to produce the comparison signal at the second dynamic node.

8. The voltage regulator circuit according to claim 7, wherein the threshold selection and shaping circuit further includes a third resistor and a bypass transistor coupled in parallel between the first dynamic node and an input of the comparator circuit, wherein the bypass transistor is fully turned on in response to the control signal being asserted and is fully turned off in response to the control signal being de-asserted.

9. A half-bridge driver circuit, comprising:
a positive supply pin;
a decoupling node; and
a floating supply pin coupled to the positive supply pin via a bootstrap path including:
a voltage regulator circuit including:
an input node coupled to the positive supply pin and configured to receive an input supply voltage;
an output node coupled to the decoupling node and configured to output an output regulated voltage;
a switchable pass element having a selectively conductive channel arranged between the input node and the output node;
a comparator circuit configured to compare the output regulated voltage to a dynamic threshold to produce a control signal to control switching of the switchable pass element, wherein the control signal being asserted results in the switchable pass element being turned on, and the control signal being de-asserted results in the switchable pass element being turned off; and
a threshold selection and shaping circuit configured to shape the output regulated voltage or the dynamic threshold so that:
in response to assertion of the control signal, a difference between the dynamic threshold and the output regulated voltage is increased and subsequently gradually decreased towards a target static value; and
in response to de-assertion of the control signal, the difference between the output regulated voltage and the dynamic threshold is increased and subsequently gradually decreased towards the target static value; and
a current limiter circuit arranged between the decoupling node and the floating supply pin.

10. The half-bridge driver circuit according to claim 9, comprising:
a ground pin;
a first control pin configured to receive a low-voltage high-side control signal for controlling a high-side switch of a half-bridge circuit;
a second control pin configured to receive a low-voltage low-side control signal for controlling a low-side switch of the half-bridge circuit;
a high-side gate driver circuit configured to receive the low-voltage high-side control signal via a level shifter circuit and produce a respective high-side gate control signal; and
a low-side gate driver circuit configured to receive the low-voltage low-side control signal and produce a respective low-side gate control signal,
wherein the high-side gate driver circuit is biased between the floating supply pin and a switching pin of the half-bridge driver circuit.

11. The half-bridge driver circuit according to claim 9, wherein the threshold selection and shaping circuit includes:
a reference node configured to receive a reference voltage;
a first circuit arrangement configured to add a first fixed voltage to the reference voltage to produce an upper static threshold;
a second circuit arrangement configured to add a first variable voltage to the upper static threshold to produce an upper dynamic threshold;
a third circuit arrangement configured to subtract a second fixed voltage from the reference voltage to produce a lower static threshold;
a fourth circuit arrangement configured to subtract a second variable voltage from the lower static threshold to produce a lower dynamic threshold,
wherein the first variable voltage is gradually decreased in response to assertion of the control signal and the second variable voltage is gradually decreased in response to de-assertion of the control signal; and
a switch configured to produce the dynamic threshold received at the comparator circuit by propagating the upper dynamic threshold in response to assertion of the control signal and propagating the lower dynamic threshold in response to de-assertion of the control signal.

12. The half-bridge driver circuit according to claim 11, wherein:
the first circuit arrangement includes a first voltage generator coupled between the reference node and a first static node to produce the upper static threshold at the first static node,
the second circuit arrangement includes a second voltage generator and a first selectively activatable RC discharge circuit coupled in parallel between the first static node and a first dynamic node, wherein the first dynamic node is coupled to the second voltage generator in response to the control signal being de-asserted and coupled to the first RC discharge circuit in response to the control signal being asserted, to produce the upper dynamic threshold at the first dynamic node,
the third circuit arrangement includes a third voltage generator coupled between the reference node and a second static node to produce the lower static threshold at the second static node, and
the fourth circuit arrangement includes a fourth voltage generator and a second selectively activatable RC discharge circuit coupled in parallel between the second static node and a second dynamic node, wherein the second dynamic node is coupled to the fourth voltage generator in response to the control signal being asserted and coupled to the second RC discharge circuit in response to the control signal being de-asserted, to produce the lower dynamic threshold at the second dynamic node.

13. The half-bridge driver circuit according to claim 11, wherein the threshold selection and shaping circuit comprises a current flow line between the input supply voltage and ground, and wherein:
the first circuit arrangement includes a first resistor arranged in the current flow line between the reference node and a first static node to produce the upper static threshold at the first static node,
the second circuit arrangement includes a second resistor and a first bypass transistor arranged in parallel in the current flow line between the first static node and a first dynamic node, wherein a conductivity of the first bypass transistor is gradually increased in response to assertion of the control signal, to produce the upper dynamic threshold at the first dynamic node,
the third circuit arrangement includes a third resistor arranged in the current flow line between the reference node and a second static node to produce the lower static threshold at the second static node, and
the fourth circuit arrangement includes a fourth resistor and a second bypass transistor arranged in parallel in the current flow line between the second static node and a second dynamic node, wherein a conductivity of the second bypass transistor is gradually increased in response to de-assertion of the control signal, to produce the lower dynamic threshold at the second dynamic node.

14. The half-bridge driver circuit according to claim 13, wherein at steady state a conductivity of the first bypass transistor and of the second bypass transistor is high.

15. The half-bridge driver circuit according to claim 9, wherein the threshold selection and shaping circuit includes:
a first circuit arrangement configured to subtract a first fixed voltage from the input supply voltage to produce a static threshold;
a second circuit arrangement configured to subtract a first variable voltage from the static threshold to produce a dynamic threshold;
a third circuit arrangement configured to subtract a second fixed voltage from the output regulated voltage to produce a static comparison signal; and
a fourth circuit arrangement configured to subtract a second variable voltage from the static comparison signal to produce a dynamic comparison signal,
wherein the first variable voltage is gradually decreased in response to de-assertion of the control signal and the second variable voltage is gradually decreased in response to assertion of the control signal, and
wherein the comparator circuit is configured to compare the dynamic threshold to the dynamic comparison signal to produce the control signal.

16. An electronic device, comprising:
the half-bridge driver circuit according to claim 10;
the high-side switch coupled between a positive bus pin and the switching pin of the half-bridge driver circuit;
the low-side switch coupled between the switching pin of the half-bridge driver circuit and the ground pin; and
a bootstrap capacitor coupled between the floating supply pin and the switching pin of the half-bridge driver circuit.

17. A method of operating a voltage regulator circuit, comprising:
receiving an input supply voltage at an input node;
producing an output regulated voltage at an output node;
comparing, by a comparator circuit, the output regulated voltage to a dynamic threshold to produce a control signal to control switching of a switchable pass element by turning on the switchable pass element in response to the control signal being asserted and turning off the switchable pass element in response to the control signal being de-asserted; and
shaping, by a threshold selection and shaping circuit, the output regulated voltage or the dynamic threshold by increasing and subsequently gradually decreasing towards a target static value a difference between the dynamic threshold and the output regulated voltage in response to assertion of the control signal, and increasing and subsequently gradually decreasing towards the target static value the difference between the output regulated voltage and the dynamic threshold in response to de-assertion of the control signal.

18. The method according to claim 17, comprising:
receiving a reference voltage;
adding a first fixed voltage to the reference voltage to produce an upper static threshold;
adding a first variable voltage to the upper static threshold to produce an upper dynamic threshold;
subtracting a second fixed voltage from the reference voltage to produce a lower static threshold;
subtracting a second variable voltage from the lower static threshold to produce a lower dynamic threshold;
decreasing the first variable voltage in response to assertion of the control signal or decreasing the second variable voltage in response to de-assertion of the control signal; and
generating the dynamic threshold by propagating the upper dynamic threshold in response to assertion of the control signal or propagating the lower dynamic threshold in response to de-assertion of the control signal.

19. The method according to claim 17, comprising:
subtracting a first fixed voltage from the input supply voltage to produce a static threshold;
subtracting a first variable voltage from the static threshold to produce a dynamic threshold;
subtracting a second fixed voltage from the output regulated voltage to produce a static comparison signal;
subtracting a second variable voltage from the static comparison signal to produce a dynamic comparison signal;
gradually decreasing the first variable voltage in response to de-assertion of the control signal or gradually decreasing the second variable voltage in response to assertion of the control signal; and
comparing the dynamic threshold to the dynamic comparison signal to produce the control signal.

20. The method according to claim 17, wherein the switchable pass element has a selectively conductive channel arranged between the input node and the output node.
